(19) United States
(12) Patent Application Publication
(10) Pub. No.: US 2024/0431036 A1
(43) Pub. Date: Dec. 26, 2024

(54) APPARATUS AND METHOD OF MAKING MODULAR INTERCONNECTIONS FOR ELECTRONIC CIRCUITS

(71) Applicant: UNIVERSITY OF SOUTH FLORIDA, Tampa, FL (US)

(72) Inventors: Mohamed Mounir ABDIN, Lutz, FL (US); Thomas WELLER, Tampa, FL (US); Jing WANG, Tampa, FL (US); William Joel Dietmar JOHNSON, Tampa, FL (US)

(21) Appl. No.: 18/703,098

(22) PCT Filed: Oct. 24, 2022
(86) PCT No.: PCT/US2022/047590

§ 371 Date: Apr. 19, 2024

Related U.S. Application Data
(60) Provisional application No. 63/271,104, filed on Oct. 22, 2021.

(51) Int. Cl. H05K 3/22

(52) U.S. Cl. CPC H05K 3/22; H05K 2203/0228; H05K 2203/107

(57) ABSTRACT

Approaches to producing modular electronic packages include modular arrangements that operate from DC up to 110 GHz and are presented using additive manufacturing such as 3D printing and laser-machining. A method includes assembling electrical circuits from circuit components positioned on modular substrate sections by identifying respective positions of selected components of the electrical circuits on an original substrate; mapping a cut path across the original substrate, wherein the cut path is determined by the respective positions of the selected components; cutting the original substrate along the cut path, wherein the cut path separates the selected components of the electrical circuits onto substrate pieces defining respective side portions; and mating the respective side portions of the respective substrate pieces with corresponding side portions of other substrate sections to assemble the electrical circuits across substrate junctions.

### CROSS REFERENCE TO RELATED APPLICATIONS

This application claims priority to and incorporates by reference U.S. Provisional Patent Application Ser. No. 63/271,104 filed on Oct. 22, 2021, entitled “Laser-Enhanced 3D Printed Highly-Integrated Modular Electronic Interconnections.”

### BACKGROUND

Electrical circuits and hardware modules often need to be replaced entirely in order to be modified or repaired. This is a time-intensive and wasteful process that also requires highly skilled labor as well as expensive specialized machinery.

A need in the industry of electronic circuits exists for a method of forming electrical circuit boards or retrofitting existing circuit boards to mix and match pieces of the circuit boards to fit together in a way that maximizes operational efficiency. The industry of electronic component manufacturing would benefit from methods that allow the reuse of circuits and hardware modules in a cost-effective technique that can be implemented with minimal skill and machinery. Prior efforts to connect new portions of circuits to pre-existing circuits often involve matching the hardware but requiring additional connectors such as wires and jumpers to provide connectivity. These additional connectors are often manually connected to a circuit board, which requires additional time and resources to complete. Current solutions are either limited to low-frequency applications (i.e. DC clip-ons) or are bulky and expensive (i.e waveguides).

### BRIEF SUMMARY OF THE DISCLOSURE

In one embodiment, a manufacturing method includes utilizing laser cutting techniques and additive manufacturing techniques, such as 3-D printing, to manufacture components of a circuit on portions of a circuit substrate. The circuit substrate can be any kind of printed circuit boards, whether traditional, additively manufactured, multi-layer or otherwise. These portions of the circuit substrate are laser cut to match pre-planned corresponding portions. Upon placing the portions and the corresponding portions in contact with each other, similar to pieces of a jigsaw puzzle, the circuit components can communicate as intended. In some embodiments, additive layers of conductive materials may be placed onto particular sections of an assembled circuit after placing the portions and corresponding portions in contact with each other to ensure proper connections and electrical communications.

In one implementation, a method converts electrical circuits, connected to a substrate, into modular sections that are configured for circuit reassembly. The method includes identifying respective positions of components of the electrical circuits on the substrate and mapping a cut path across the substrate, wherein the cut path is determined by the respective positions of the components. By cutting the substrate along the cut path, the cut path separates the components of the electrical circuits onto respective substrate sections defining respective side portions.

The method may further include mapping the cut path to minimize damage to the components of the electrical circuits.

The method may further include mapping the cut path to cross transmission lines connecting the circuit components and avoiding the circuit components on the substrate.

The method may further include cutting the substrate with a laser. The method may further include using the laser to make a separating cut through the electrical circuits and the substrate, wherein the separating cut is less than or equal to 100 microns wide.

The method may utilize a separating cut that is within a width range selected from 1 micron to 5 microns, 5 microns to 10 microns, 10 microns to 20 microns, 20 microns to 30 microns, 30 microns to 40 microns, 40 microns to 50 microns, 50 microns to 75 microns, and 75 microns to 100 microns or greater.

The method may include cutting the substrate with a laser and using the laser to make a separating cut that is 15 microns wide.

The method may include cutting the substrate to define the side sections in a jigsaw pattern that accommodates the reassembly.

The method may include forming side portions that are cut in a pattern that provides self-alignment of mating substrate sections when corresponding side portions of the substrate sections fit together.

In another implementation, a method provides for assembling electrical circuits from circuit components positioned on modular substrate sections. The method includes identifying respective positions of selected components of the electrical circuits on an original substrate and mapping a cut path across the original substrate, wherein the cut path is determined by the respective positions of the selected components. The method includes cutting the original substrate along the cut path, wherein the cut path separates the selected components of the electrical circuits onto substrate pieces defining respective side portions and mating the respective side portions of the respective substrate pieces with corresponding side portions of other substrate sections to assemble the electrical circuits across substrate junctions.

The method may be implemented with the other substrate sections including either certain components from the original substrate or new components that were originally positioned on a different substrate.

The method may include cutting the original substrate with a laser.

The method may include cutting the original substrate with a pico-second pulsed laser.

The method may include adding conductive interconnects across the substrate junctions to provide electrical transmission lines across the substrate junctions and between respective circuit components on opposite sides of a respective substrate junction.

The method of adding the conductive interconnects may include using three dimensional printing to apply conductive metal over the substrate junctions.

The method of adding the conductive interconnects may include printing silver paste as the conductive metal.

The method of cutting the original substrate with a laser may include using the laser to make a separating cut that is 15 microns wide.

In another implementation, an electrical circuit on a substrate includes a plurality of modular substrate sections having circuit components thereon, with the modular substrate sections connected at substrate junctions between the modular substrate sections. The substrate junctions include respective side portions of respective substrate pieces mated with corresponding side portions of other substrate sections. The conductive interconnects are positioned over sections of the substrate junctions to provide conductive electrical transmission lines between at least two circuit components that are on opposite sides of a respective substrate junction.

In some implementations, the conductive interconnects are printed metallic ink forming conductive metallic bridges over the substrate junctions.

In some implementations, the electrical circuit utilizes epoxy filler connecting the modular substrate sections at the substrate junctions.

### BRIEF DESCRIPTION OF THE FIGURES

The patent application file or the patent issuing therefrom contains at least one drawing described below.

FIG. 1A is a schematic representation of an electronic circuit divided onto separate portions of a circuit substrate that has been cut and separated into two separate components that fit together for a modular installation according to aspects of this disclosure.

FIG. 1B is a schematic representation of the electronic circuit of FIG. 1A wherein the separate portions fit together to re-establish electronic communications between the two separate portions according to aspects of this disclosure.

FIG. 1C is a schematic representation of the electronic circuit of FIG. 1A wherein the separate portions of the substrate and circuit fit together to re-establish electronic communications between the two separate portions and the communications have been enhanced by an overlay of conductive layers over the intersection points of the circuit.

FIG. 2A is a schematic representation of an electronic circuit, namely an example transmitter and receiver circuit, divided onto separate portions of a circuit substrate that has been divided into separate components that fit together for a modular installation.

FIG. 2B is a schematic representation of the electronic circuit of FIG. 2A wherein the separate portions fit together to re-establish electronic communications between the separate portions in a snap-on circuit board.

FIG. 3A is a cross section representation of an electronic circuit prior to a cut according to aspects of this disclosure, wherein a cut path can be mapped to separate circuit components onto respective substrate portions that can be re-assembled with the same or new substrates to re-establish electronic communications between the two separate portions.

FIG. 3B is a close up cross section representation of an electronic circuit wherein the separate portions fit together to re-establish electronic communications between the two separate portions and the communications have been enhanced by an overlay of conductive layers over the intersection points of the circuit substrate junctions.

FIG. 4A is a schematic representation of transmission line portions of an electronic circuit on a circuit substrate that includes at least two corresponding circuit sections that work in connection with an overall electronic communications scheme and illustrating cutting the circuit according to techniques of this disclosure.

FIG. 4B is a schematic representation of an overall electronic circuit that includes the transmission lines of FIG. 4A, in which the circuit substrate has been divided into sections by a cutting technique so that the original circuit substrate is divided into two corresponding circuit sections that work in connection with an overall electronic communications scheme.

FIG. 5A is a close-up image of a section of a circuit that includes transmission lines and grounded regions subject to cutting according to aspects of this disclosure.

FIG. 5B is a close-up image of the transmission lines and grounded regions of FIG. 5A after being subject to cutting and separated according to aspects of this disclosure.

FIG. 5C is a close-up image of the transmission lines and grounded regions of FIG. 5A after being subject to cutting and separated and then re-connected with interconnecting metallic bridges according to aspects of this disclosure.

FIG. 5D is a graphical representation of a graph of the power response in terms of S-parameters according to input frequencies of a transmission line that has been fabricated according to the disclosures herein.

FIG. 6A is a schematic representation of an electronic circuit on a substrate that has been divided into sections that each include at least one of two corresponding circuit sections that work in connection with an overall electronic communications scheme. FIG. 6A shows how the cutting techniques of this disclosure allow for testing access for one portion of the modular circuit described herein.

FIG. 6B is a graphical representation of a graph of the forward gain power response in terms of S-parameters according to input frequencies of the circuit of FIG. 6A that has been fabricated according to the disclosures herein.

FIG. 6C is a graphical representation of a graph of the reflected gain power response in terms of S-parameters according to input frequencies of the circuit of FIG. 6A that has been fabricated according to the disclosures herein.

FIG. 7A is a top plan view of an overall electronic circuit that has been cut according to aspects of this disclosure and shows the width of the cuts as well as substrate junctions in a jigsaw pattern prior to separation.

FIG. 7B is a top plan view of an overall electronic circuit that has been cut according to aspects of this disclosure and then separated at the substrate junctions to allow for testing access of two different sections of the circuit.

FIG. 7C is a top plan view of an overall electronic circuit that has been cut according to aspects of this disclosure and then reassembled at substrate junctions that join in a jigsaw pattern according to aspects of this disclosure.

FIG. 8A is a graphical representation of a graph of the forward gain power response in terms of S-parameters according to input frequencies of the re-assembled circuit of FIG. 7C that has been fabricated according to the disclosures herein.

FIG. 8B is a graphical representation of a graph of the reflected gain power response in terms of S-parameters according to input frequencies of the circuit of FIG. 7C that has been fabricated according to the disclosures herein.

### DETAILED DESCRIPTION

In some aspects, the present disclosure relates to computerized apparatuses, computer implemented methods, and computerized systems that use a laser cutting tool to cut a circuit into two different portions that can be re-connected. The cutting may cut the circuit into different components but also may cut a circuit substrate (e.g. a circuit board) into different components. A circuit can be designed or modified with the intention of being modularly connected. In non-limiting embodiments, the circuit or modular sections to be connected are laser-machined in a jigsaw pattern to produce cuts as small as 15 um without damaging surrounding circuitry. In one example implementation, transmission lines (including but not limited to grounded coplanar waveguides (GCPW)) are used at the interface of the connections. The modules are then attached (snapped-on) and are self-aligned and is mechanically sturdy. The use of adhesives can be used to reinforce the connections at the jigsaw interface. In non-limiting examples, conductive silver paste is additively manufactured across GCPW transmission lines and dried.

In some embodiments, this disclosure provides a light, compact, economical, and high performing electrical interconnection to connect modular designs. In one example, this disclosure provides modular components in the form of grounded coplanar waveguides (GPCW) that operate up to 110 GHZ.

Electrical circuits/modules that are designed often need to be replaced entirely in order to be modified or repaired. This is a time-intensive and wasteful process that also requires highly skilled labor as well as expensive specialized machinery. This disclosure allows the re-use of circuits and substrate modules using a cost-effective technique that can be implemented with minimal skill and machinery.

Some non-limiting aspects of this disclosure show a process and associated apparatus for modular integration of circuit components without bulky connectors and jumpers providing the requisite connectivity. The modularity of the substrates allows interchangeable re-assembly of mm-wave transceivers. As discussed below; the implementations of this disclosure have been used to test sub-system transmitter, receiver, antennas, and a GCPW (Grounded Coplanar-waveguide) transmission-line test-feature. These example tests are not limiting of the disclosure. Other factors making the method and apparatus more specialized include high frequency operation (at least up to 110 GHz), compactness, small size, and full integration on any kind of substrates. The module to module mechanical attachment at reassembly of the modular components ensures a self-alignment feature that has not been shown previously.

Aspects of this disclosure enable converting circuits and packages from non-modular to modular design by properly planning the cut path described below. In some examples, the cuts provide a 42:1 aspect-ratio (e.g., 15 um-wide cuts through a 630 um-thick substrate). The examples described herein show that the substrate was demonstrated with minimal changes to the substrate and performance. The proposed modular process can also be used to interchange components or allow attachment of different substrates with different thicknesses or permittivities, such as integrating high permittivity and low-permittivity substrates for MMIC circuits and antennas, respectively.

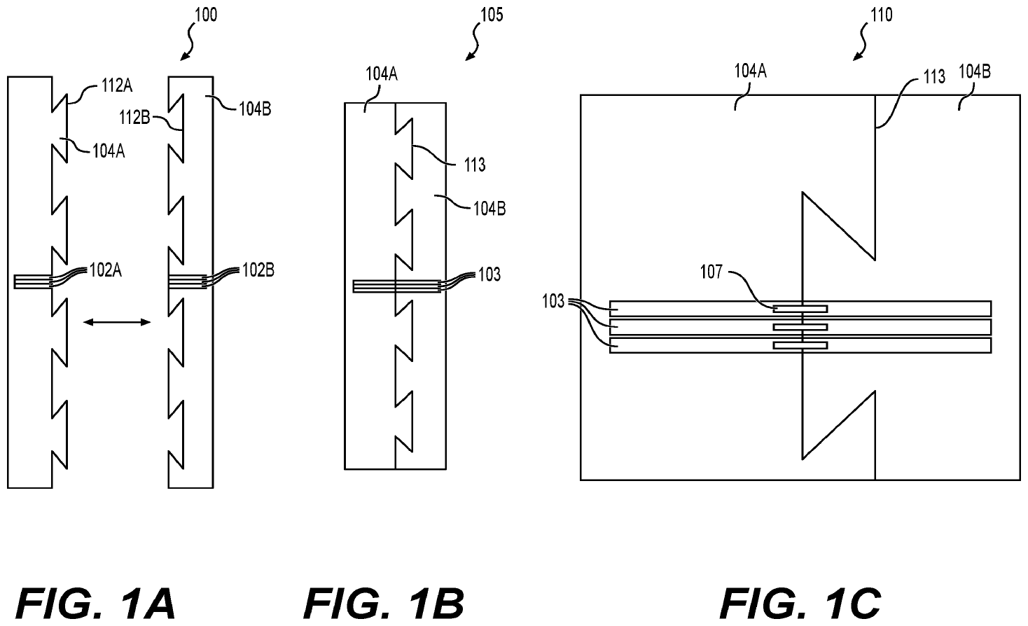

In the example of FIGS. 1A-1C, distinct portions of a commonly used circuit 100, 105, 110 have been manufactured on laser cut circuit substrates 104A and 104B that fit together, and break apart, in modular fashion. Electronic communications across particular circuit components 102A, 102B can be established when corresponding portions 112A, 112B of the circuit substrate connect at intersection lines, or substrate junctions, 113 of FIG. 1B so that an overall electrically conductive path 103 is established. For extra reinforcement of conductivity, a layer 107 of a conductive material, such as a layer of silver metal, may be added to appropriate regions of the aligned and connected corresponding portions. This arrangement allows for portions of a circuit to be replaced without disassembling an entire apparatus. FIG. 1C shows the overall electrically conductive path 103, and portions 112A and 112B can be mixed and match with appropriate replacement portions as needed, so long as the replacement portions have the matching cut designs along the intersection lines 113.

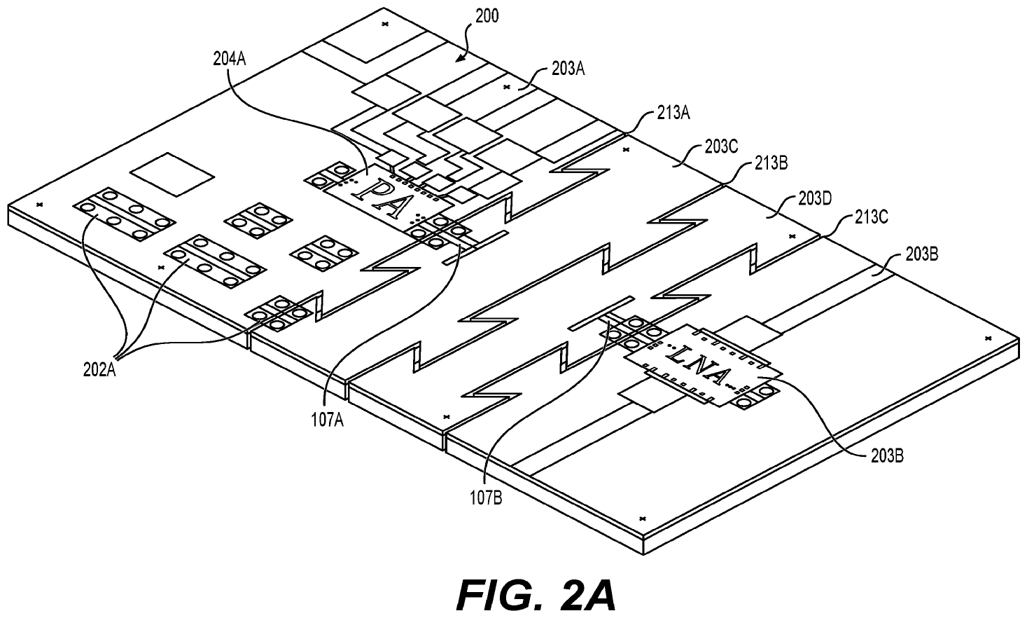

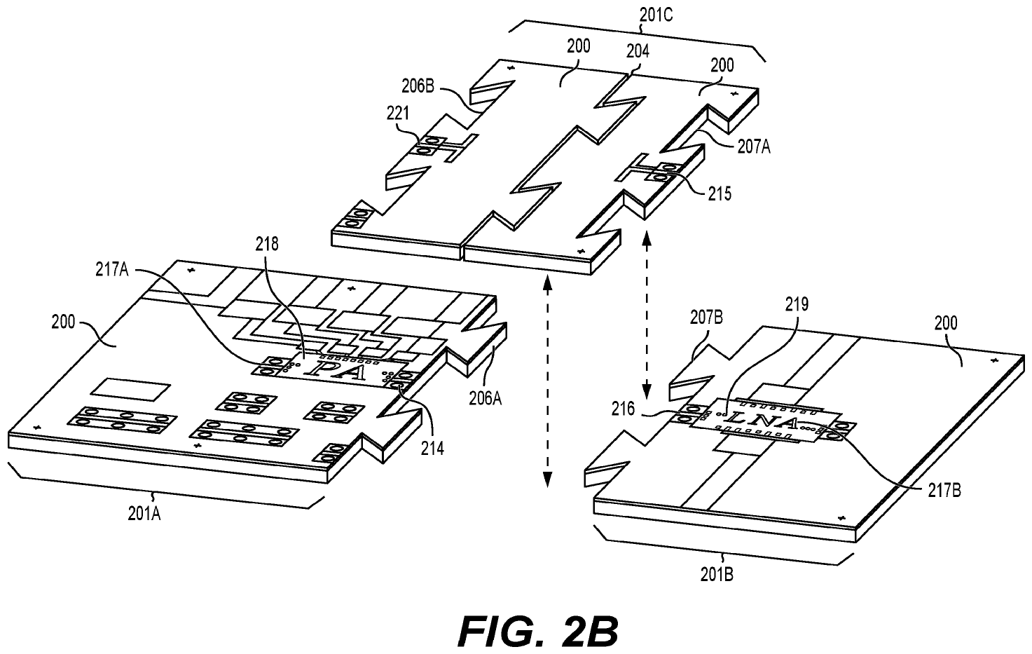

FIGS. 2A and 2B illustrate the concepts of this disclosure in the context of the above noted grounded coplanar waveguides (GPCW), which is one non-limiting example of circuits that can be used with this disclosure and the associated techniques. Circuit components of the GPCW are intended to be connected on an overall circuit substrate 200. The substrate, however, may have been cut, such as but not limited to laser cut, to divide the assembly into components that can be disconnected into respective substrate pieces 203A, 203B, 203C, 203D. The substrate pieces may be disconnected and then reassembled as discussed herein. The separability of the circuit substrate 200 is shown by the disconnects, or cuts, at references 213A, 213B, 213C, and 213D formed by laser cut dovetails shown in FIG. 2B at references 207A and 207B, which are only example kinds of cuts.

FIG. 2B illustrates how these respective substrate pieces may be separated after the cutting procedures and the substrate pieces are configured to be placed back together to form a functioning circuit again. Reconnected substrate pieces may be attached by an adhesive epoxy filler at the substrate junctions 213A, 213B, 213C, 213D. In the non-limiting examples of FIGS. 2A and 2B, the modular transmission circuit 203A can be divided by a disconnecting cut so that portions of the transmission circuit 203A are on opposite sides of the substrate junction 213A of FIG. 2A. The same is true for the modular receiver circuit 203B that can be divided by disconnect cut so that portions of the receiver circuit 201B are on opposite sides of the substrate junction 213C of FIG. 2A. In FIG. 2A, a cut according to this disclosure has been mapped to route through respective transmission line portions 107A, 107B on both sides of the antenna circuit 203A, 203B. The cut path that has been mapped to make the cut and form modular, reconnectable substrate portions can take any turns and cross any circuit components that is desired. In FIG. 2A, certain test transmission lines 202A may be included on a circuit board or substrate for experimental purposes and be subject to cutting first. In the example of FIG. 2A, the cut paths would avoid damaging a power amplifier 204A on the transmission circuit 203A and avoid damaging a low noise amplifier 204B on the receiver circuit 203B.

FIG. 2B illustrates more details of how a cut substrate or printed circuit board of any type can utilize the techniques of this disclosure to separate and then reassemble a circuit with either new components or the same components depending on the situation. The circuit of FIG. 2B is an example antenna circuit that utilizes a transmission circuit 217A having a power amplifier 218 and grounded transmission lines 214/221 that have been separated by a laser cut 213A according to this disclosure. Similarly, a receiver circuit 217B includes the above noted low noise amplifier 219 having grounded transmission lines 215/216 that that have been separated by a laser cut 213C according to this disclosure. The cutting process of this non-limiting example separates the antenna circuit of FIG. 2B into three respective substrate sections 201A, 201B, 201C. A different cut 204 provides more flexibility to possibly divide the substrate even further. The dovetail cuts of this example FIG. 2B allow for matching the side portions 206A with a corresponding side portion 206B and similarly 207A and 207B of respective substrate pieces 201A, 201B, 201C to re-assemble the circuit at substrate junctions. The cut path of this example in FIG. 2B allows for reassembling along transmission lines as shown by the pairs at 214/221 and 215/216 being placed back together to make a fully functional circuit. In some embodiments, the same pieces are put back together, such as after testing and repair, and in other cases one or more of the substrate pieces can be an entirely new circuit section that was originally formed on a completely different substrate but cut to match the cut path of the original circuit.

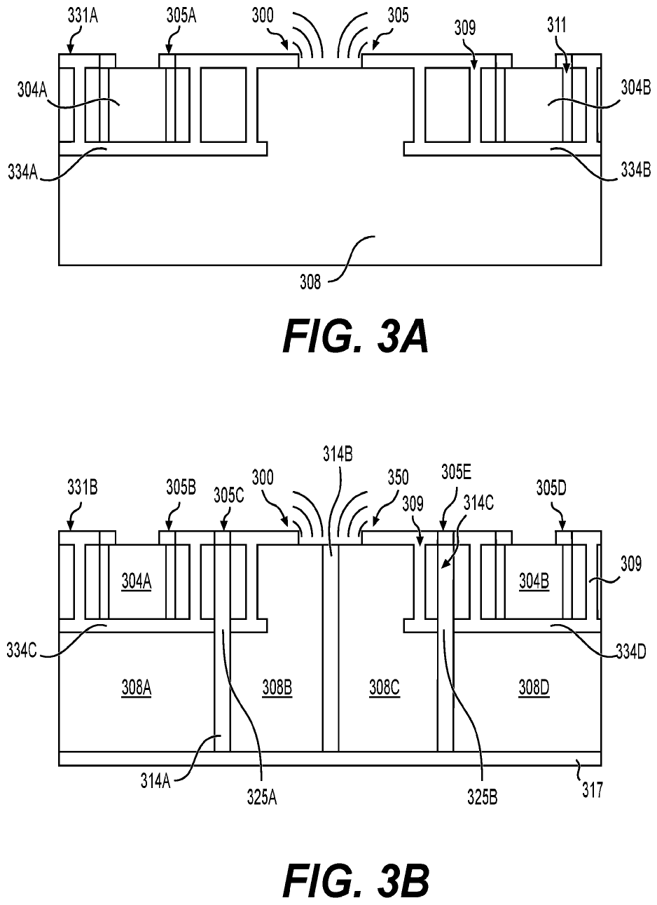

FIGS. 3A and 3B show examples of how the techniques of this disclosure can be used in one example scenario in which a transmitter and a receiver are fabricated as a system on a package and then tested by the cutting described herein. The example shows how to make three cuts yielding a modular approach to circuit fabrication. The three cuts divide a substrate into a transmission module 300, a receiver module 350 and an overall antenna pair module. The cuts give testing access to each module and then allow for reassembly as discussed above. In this way, the techniques disclosed herein allow for characterizing the performance of each module before reassembling. In FIG. 3A, a substrate 308, whether a traditional printed circuit board or additively manufactured circuit board or other kind of substrate, supports a transmitter module 300 having a power amplifier 304A, transmission line circuitry 331A, an original transmission interconnect 305A, and a micro-dispensed ground layer 334A. The substrate 308 also supports a receiver module 350 having, for example, a low noise amplifier 304B, vias 309, gap fill 311, original interconnect 305D, and the micro-dispersed ground 334B.

FIG. 3B illustrates how cutting the circuit into discrete modules, for example, with a laser, can provide alternatives for circuit testing and fabrication. As noted, a cut path is mapped to avoid damaging the above referenced components but also provide modular sections for separation and reconnection. FIG. 3B illustrates a cross section of the circuit after modular cutting and reassembly. For example purposes only, and without limiting this disclosure to any one embodiment, FIG. 3B illustrates using coplanar wave guides as the cutting and separation points. The coplanar waveguides are then reconnected as shown and conductive metallic bridges, or conductive interconnects 305C, 305E, are connected over the substrate junctions 314A, 314C to ensure connectivity between the modular portions 308A, 308B, 308C, 308D of the circuit assembly. The substrate junctions may be filled with an adhesive or epoxy as needed. An optional RF absorber layer 317 is shown as a bottom layer. FIG. 3B illustrates how after reassembly the ground layer 334A, 334B may be a separated ground region 325A, 325B. The reassembled circuit is ready for use but may have had individual components tested separately, moved to different distances, or replaced all together in the modular reconstructions shown herein.

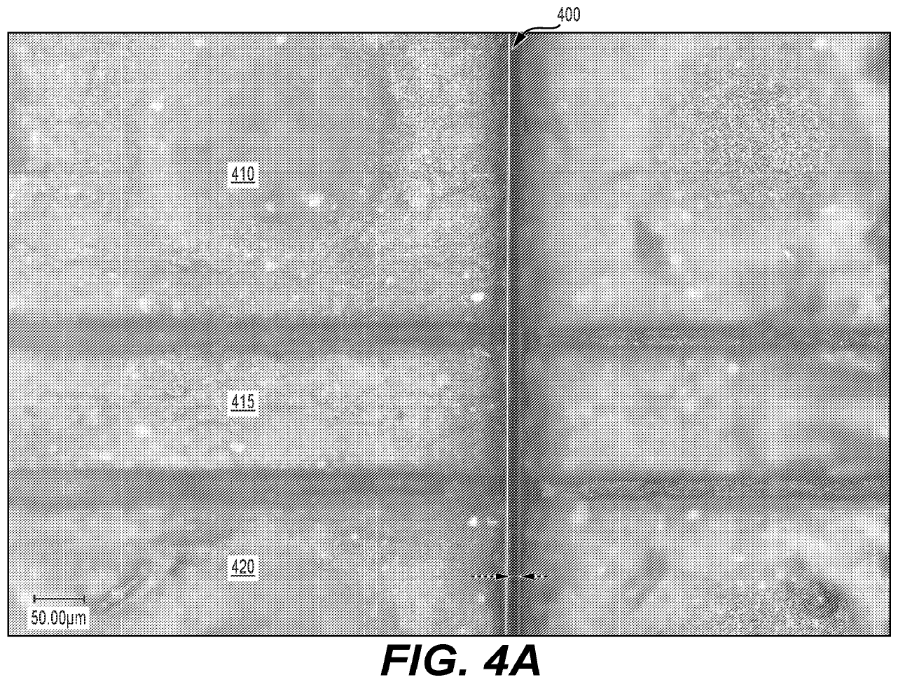

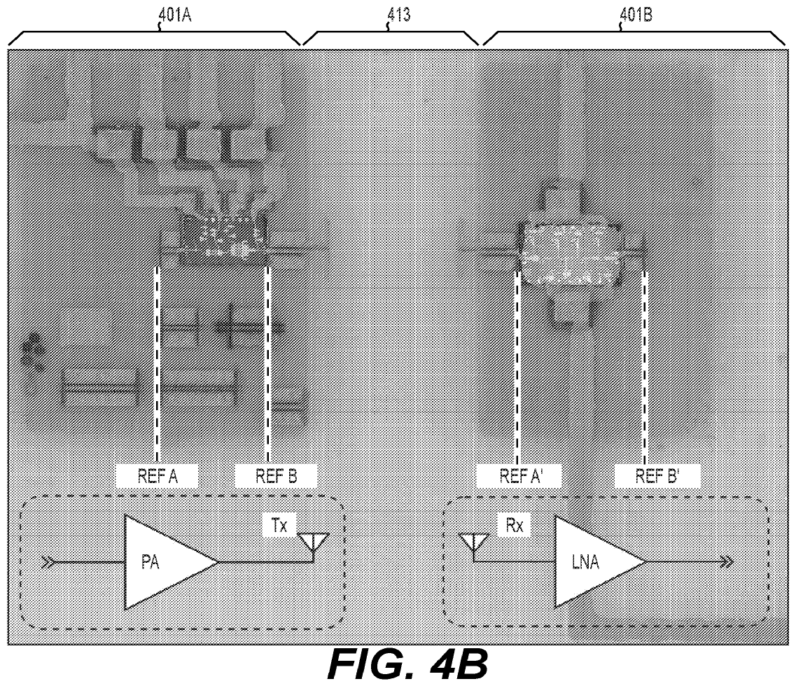

FIG. 4A is a close up view of one set of transmission lines that can be an example of how a cut path can be mapped to separate a circuit at points that make reassembly the easiest and most viable option. Reference 400 is just one example of a cut, but it is around 15 microns in width and cuts through the signal line 415 and ground lines 410, 420. In non-limiting examples, a laser may be used to perform the cutting.

FIG. 4B is a broader view of an example circuit that can be cut according to this disclosure. As illustrated, the cutting can follow a cut path to allow access for testing a transmitter circuit 401A between Reference Points A and B or testing a receiver circuit 401B between Reference Points B′ and A. The example of FIG. 4B is not limiting of this disclosure but illustrates how a cut path can be planned to avoid damaging circuit components but provide for the modular sections to be accessed, tested, and even replaced separately from one another. This example is actually a W-Band integrated front end of an antenna circuit on a multilayer substrate, which may be subject to additive manufacturing techniques such as three dimensional printing. In this embodiment, the example includes an antenna on package (AoP) assembly connected with grounded co-planar wave guide (GCPW) to co-planar stripline (CPS) transition. This is an example of the kind of circuit that can be subject to the cutting and reassembly of this disclosure.

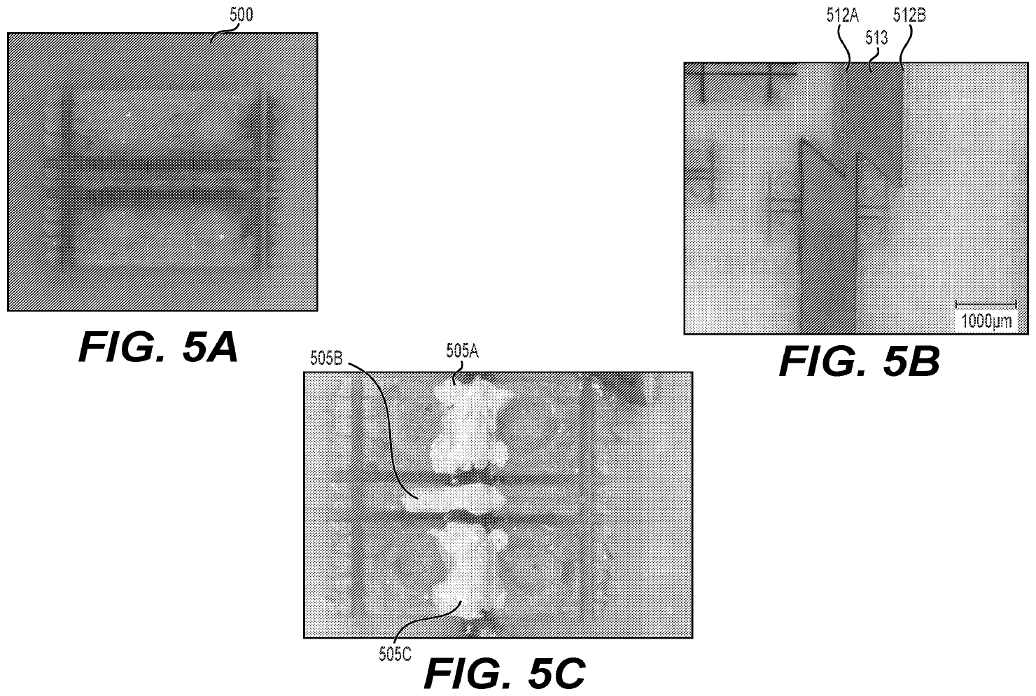

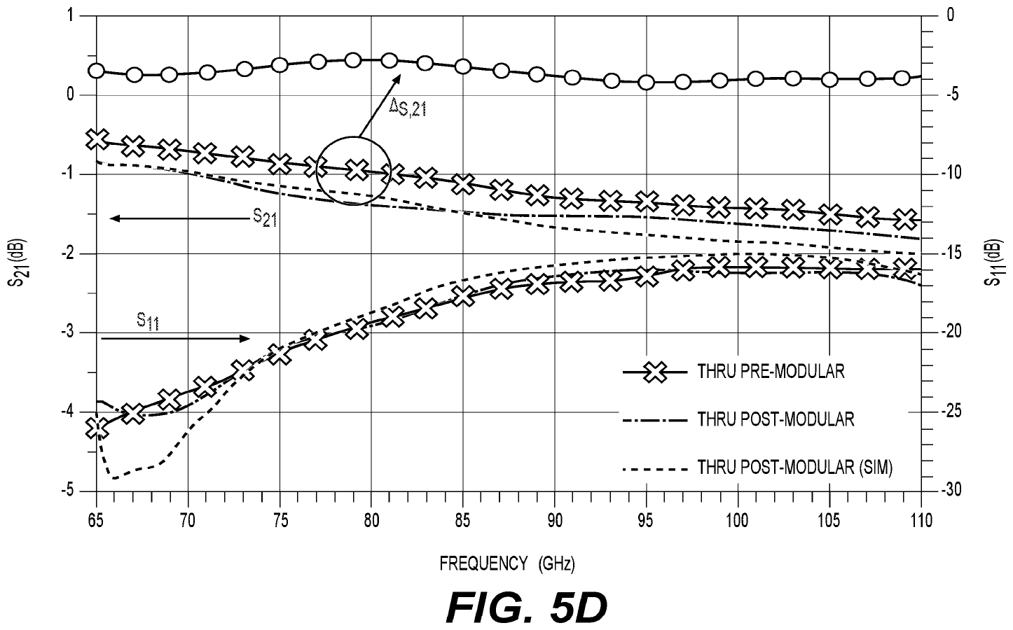

FIGS. 5A through 5D illustrate another example circuit that can be used to illustrate the effectiveness of the cutting and reassembly techniques of this disclosure. FIG. 5A illustrates the grounded co-planar waveguide 500 may be fabricated on any kind of substrate as discussed above. FIG. 5B illustrates the separation 513 of the modular sections after a laser cut across the waveguide. FIG. 5C illustrates the reassembly along the respective sides 512A and corresponding sides 512B of the cut circuit component 500. The techniques described herein may include, but are not limited to applying a metallic interconnect to re-establish the grounds 505A, 505C, and signal lines 505B after reassembly. FIG. 5D illustrates the graphical representation of the power response in terms of S-parameters according to input frequencies of a transmission line that has been fabricated according to the disclosures herein. It is notable that in this example, the return loss is minimally affected. The gain degraded by about 0.5 dB loss for the full frequency range. The interconnects, which may be a silver ink applied with 3D printing techniques, provide ohmic contact resistance between new and old layers, but overall, the loss remains flat.

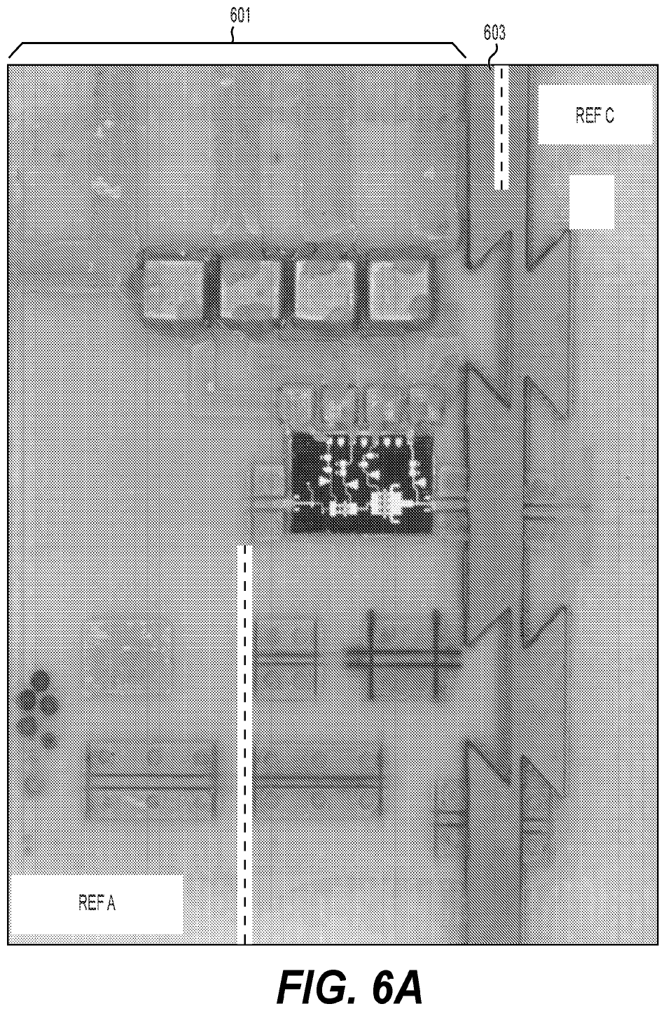

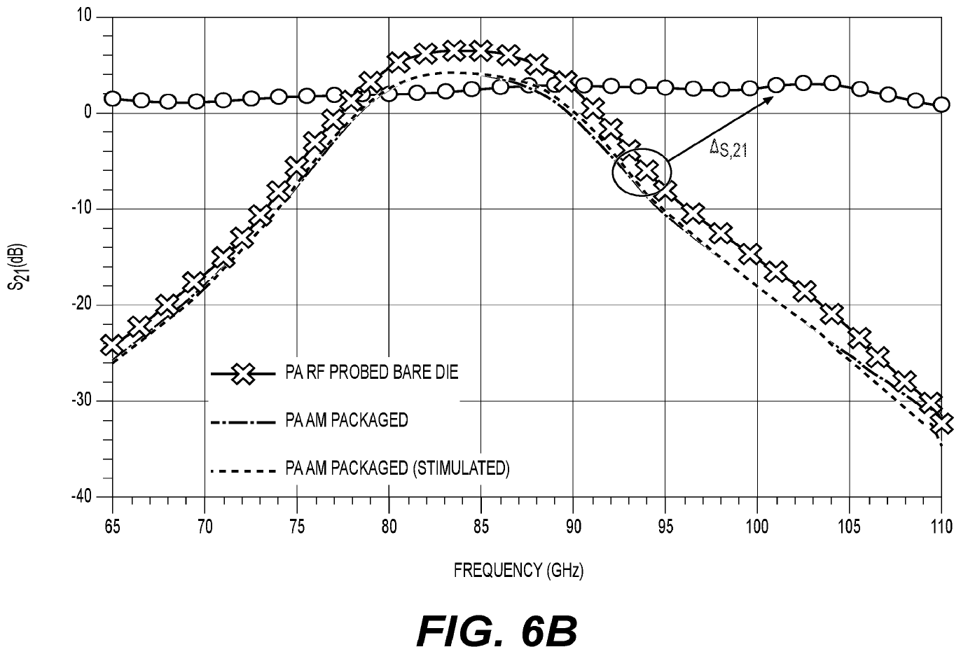

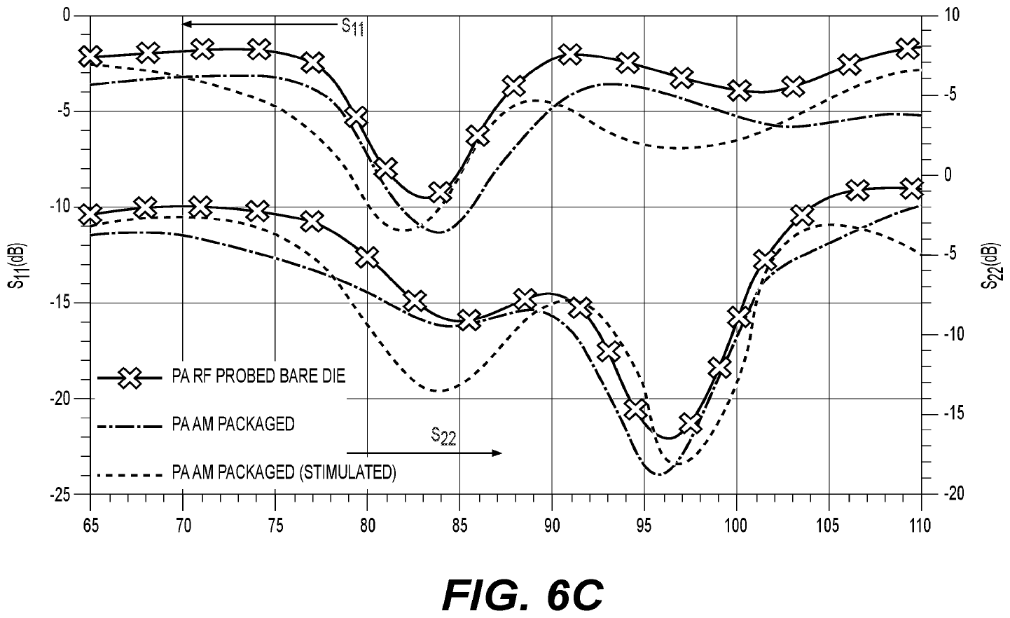

FIGS. 6A through 6C provide a similar, non-limiting example implementation of this disclosure that illustrates cutting a circuit into modular assemblies and then testing one component. In this example, the test was conducted on a modular power amplifier circuit 601 to provide access points to test the power amplifier at Reference Points A and C after separating the module at distance 613. FIGS. 6B and 6C illustrate that the gain and return loss are closely agreeing to the simulated S-parameters. Overall there is a 2 dB package loss at 80 GHZ, and chip to board interconnects loss is 0.1 dB per interconnect (0.55 dB/mm). This kind of testing would not be possible without the modular nature of the assembly.

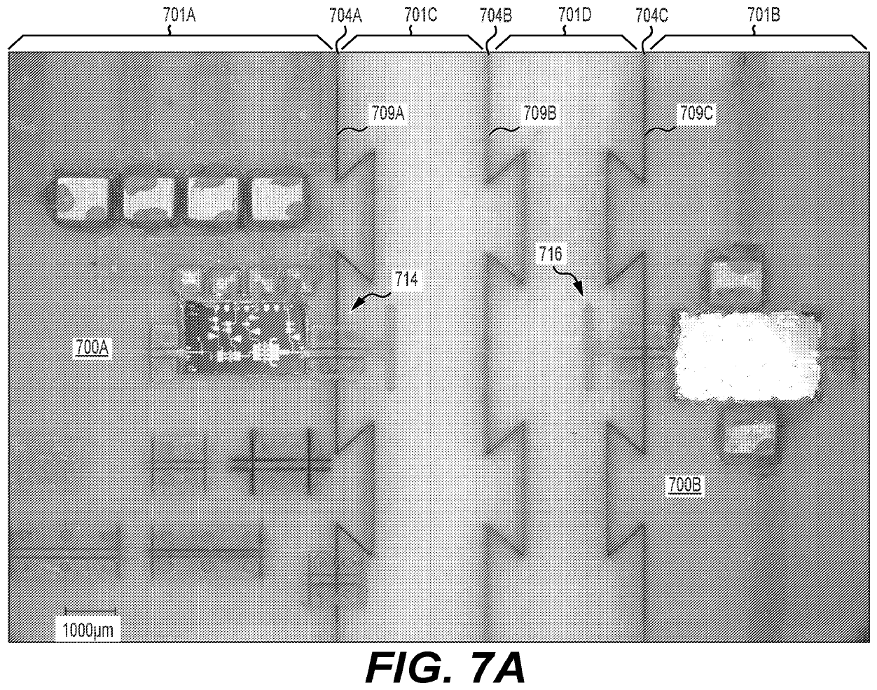

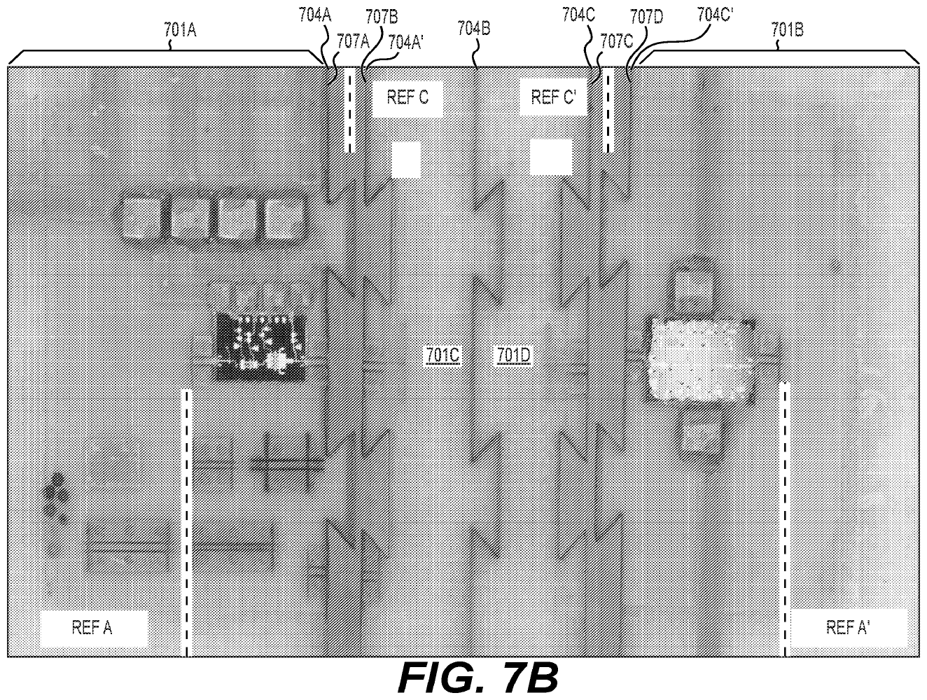

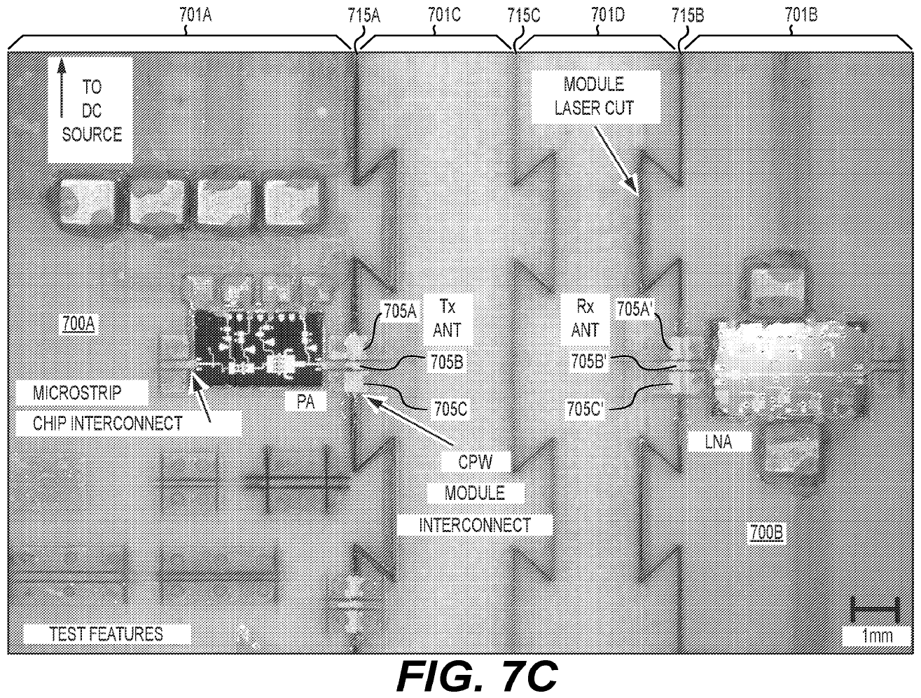

FIGS. 7A and 7B illustrate a comprehensive example of this disclosure. These figures illustrate a method of converting electrical circuits connected to a substrate into modular sections 701A, 701B, 701C, 701D and configured for circuit reassembly. The method may include identifying respective positions of components of the electrical circuits on the substrate; mapping a cut path across the substrate, wherein the cut path is determined by the respective positions of the components; and cutting the substrate along the cut paths 704A, 704B, 704C, wherein the cut paths separate the components of the electrical circuits 700A, 700B onto respective substrate sections defining respective side portions 707A, 707B, 707C, 707D. Mapping the cut path is conducted strategically to minimize damage to the components of the electrical circuits. In the non-limiting example of FIGS. 7A-7C, mapping the cut path included a determination to cut across transmission lines 714, 716 connecting the circuit components and avoiding other circuit components on the substrate that make up the overall electronic circuits 700A, 700B.

In non-limiting examples, cutting the substrate includes cutting the substrate with a laser. In another non-limiting embodiment, the laser is a pico-second pulsed laser but other lasers (e.g., femto-lasers are optionally used). The laser may make a separating cut 709A, 709B, 709C through the electrical circuits and the substrate, wherein the separating cut is less than or equal to 100 microns wide. In other non-limiting embodiments, the separating cut is within a width range selected from 1 micron to 5 microns, 5 microns to 10 microns, 10 microns to 20 microns, 20 microns to 30 microns, 30 microns to 40 microns, 40 microns to 50 microns, 50 microns to 75 microns, and 75 microns to 100 microns. The width of the cut can be greater than 100 microns depending upon the frequency response needed. Several examples of this disclosure implement cutting the substrate with a laser and using the laser to make a separating cut that is 15 microns wide. The cutting of the substrate may define the side sections in a jigsaw pattern that accommodates the reassembly. The jigsaw patterns are non-limiting as the cut path can achieve any pattern that is desired for the case at hand. In non-limiting embodiments, the side portions 707A, 707B, 707C, 707D are cut in a pattern that provides self-alignment of mating substrate sections when corresponding side portions of the substrate sections fit together.

FIG. 7C illustrates a method of assembling electrical circuits 700A, 700B from circuit components positioned on modular substrate sections 701A, 701B, 701C, 701D. The method includes identifying respective positions of selected components of the electrical circuits on an original substrate and mapping a cut path 704A, 704B, 704C across the original substrate, wherein the cut path is determined by the respective positions of the selected components. In non-limiting embodiments, a laser is used for cutting the original substrate along the cut path, wherein the cut path separates the selected components of the electrical circuits onto substrate pieces 701A, 701B, 701C, 701D defining respective side portions 707A, 707B, 707C, 707D. The method includes reassembling the circuit by mating the respective side portions of the respective substrate pieces with corresponding side portions of other substrate sections to assemble the electrical circuits across substrate junctions. In this way, the above noted “other substrate sections” can be either certain components from the original substrate or new components that used to be positioned on a different substrate. In other words, the techniques of this disclosure allow for trading out components for whatever reason after testing them. Similar to the method above, cutting the original substrate may be done with a laser, and in some embodiments, with a pico-second pulsed laser. Any short pulse laser will be sufficient. For instance, there is also an opportunity to use a “femtosecond laser”, which can support “cold ablation” with the same quality of cut (high aspect ratio, etc.) if not better than that of pico-second laser cutting. Once the components are put back together along substrate junctions 715A, 715B, 715C, the method may include adding conductive interconnects 705A, 705B, 705C and 705A″, 705B′, 705C′ across the substrate junctions to provide electrical transmission lines across the substrate junctions and between respective circuit components on opposite sides of a respective substrate junction. Adding the conductive interconnects includes using three dimensional printing to apply conductive metal over the substrate junctions. Adding the conductive interconnects may include printing silver paste as the conductive metal. The conductive interconnects may include multiple layers, such as patterned layers of conductive metals and dielectric layers. The non-limiting example of FIG. 7C make the cuts with a laser and uses the laser to make a separating cut that is 15 microns wide. Other dimensions are within the scope of this disclosure.

Overall, FIG. 7C illustrates a reassembled circuit that may be described, in non-limiting examples, as an electrical circuit on a substrate having a plurality of modular substrate sections with circuit components thereon. After reassembling the modular substrate sections, there are substrate junctions between the modular substrate sections, wherein the substrate junctions have respective side portions of respective substrate pieces mated with corresponding side portions of other substrate sections. The conductive interconnects are positioned over sections of the substrate junctions to provide conductive electrical transmission lines between at least two circuit components that are on opposite sides of a respective substrate junction. As noted, the conductive interconnects may include any printed metallic ink forming conductive metallic bridges over the substrate junctions. Epoxy filler may be used to connect the modular substrate sections at the substrate junctions.

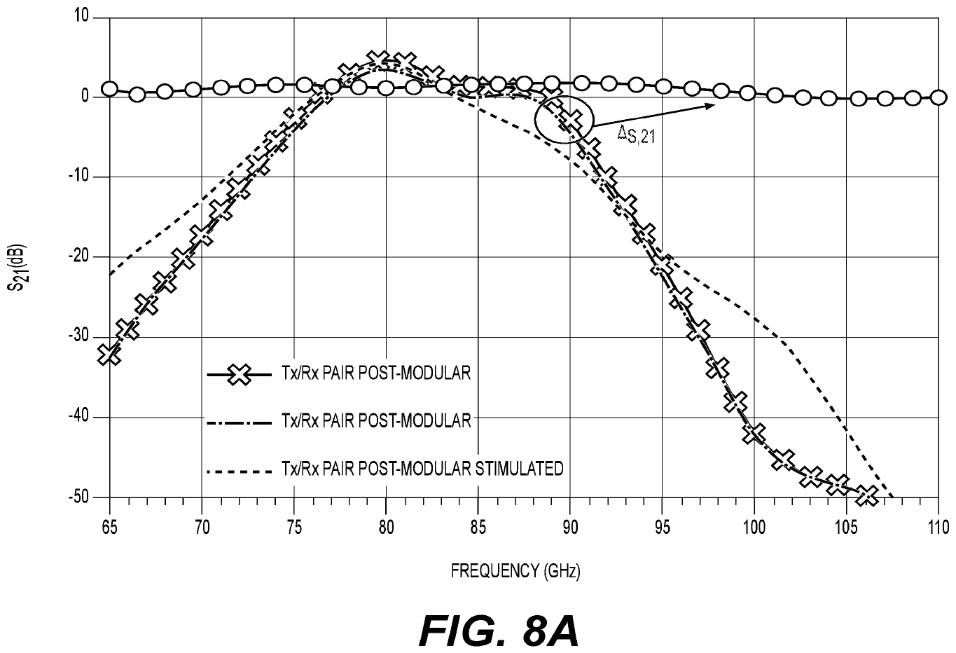

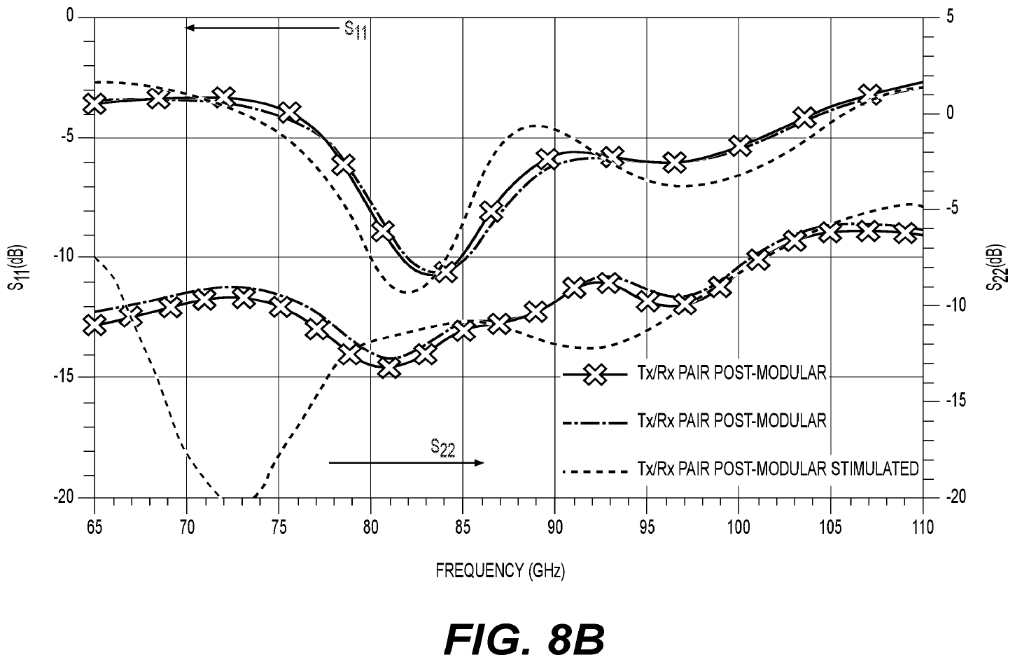

FIG. 8A is a graphical representation of a graph of the forward gain power response in terms of S-parameters according to input frequencies of the re-assembled circuit of FIG. 7C that has been fabricated according to the disclosures herein.

FIG. 8B is a graphical representation of a graph of the reflected gain power response in terms of S-parameters according to input frequencies of the circuit of FIG. 7C that has been fabricated according to the disclosures herein.

In another embodiment, instead of cutting a substrate to define side portions 707A, 707B, 707C, 707D, for example, a printed circuit board can be fabricated or manufactured in a particular shape to match different pieces of a substrate and the circuits thereon. For example, the side portions of modular substrate pieces may be fabricated by additive manufacturing, milling, or any fabrication process so that side portions of respective substrate pieces can mate with corresponding side portions of other substrate sections. Each specialized piece may have particular parts of an overall electronic circuit thereon. Once the pieces are placed together across a substrate junction, the conductive interconnects may be added, again possibly by additive manufacturing or 3D printing, to ensure transmission from one of the specially shaped pieces to another. This portion of the disclosure would eliminate the cutting by simply manufacturing pieces in the appropriately connectable shape.

These and other aspects of the disclosure are shown in the figures and abstract and set forth in the claims that follow.

1. A method of converting electrical circuits connected to a substrate into modular sections configured for circuit reassembly, the method comprising:
identifying respective positions of components of the electrical circuits on the substrate;
mapping a cut path across the substrate, wherein the cut path is determined by the respective positions of the components;
cutting the substrate along the cut path, wherein the cut path separates the components of the electrical circuits onto respective substrate sections defining respective side portions.

2. The method of claim 1, further comprising mapping the cut path to minimize damage to the components of the electrical circuits.

3. The method of claim 1, further comprising mapping the cut path to cross transmission lines connecting the circuit components and avoiding the circuit components on the substrate.

4. The method of claim 1, further comprising cutting the substrate with a laser.

5. The method of claim 4, further comprising using the laser to make a separating cut through the electrical circuits and the substrate, wherein the separating cut is less than or equal to 100 microns wide.

6. The method of claim 5, wherein the separating cut is within a width range selected from 1 micron to 5 microns, 5 microns to 10 microns, 10 microns to 20 microns, 20 microns to 30 microns, 30 microns to 40 microns, 40 microns to 50 microns, 50 microns to 75 microns, and 75 microns to 100 microns.

7. The method of claim 1, further comprising cutting the substrate with a laser and using the laser to make a separating cut that is 15 microns wide.

8. The method of claim 1, further comprising cutting the substrate to define the side sections in a jigsaw pattern that accommodates the reassembly.

9. The method of claim 1, wherein the side portions are cut in a pattern that provides self-alignment of mating substrate sections when corresponding side portions of the substrate sections fit together.

10. A method of assembling electrical circuits from circuit components positioned on modular substrate sections, the method comprising:
identifying respective positions of selected components of the electrical circuits on an original substrate;
mapping a cut path across the original substrate, wherein the cut path is determined by the respective positions of the selected components;
cutting the original substrate along the cut path, wherein the cut path separates the selected components of the electrical circuits onto substrate pieces defining respective side portions; and
mating the respective side portions of the respective substrate pieces with corresponding side portions of other substrate sections to assemble the electrical circuits across substrate junctions.

11. The method of claim 10, wherein the other substrate sections comprise either certain components from the original substrate or new components positioned on a different substrate.

12. The method of claim 10, further comprising cutting the original substrate with a laser.

13. The method of claim 12, further comprising cutting the original substrate with a pico-second pulsed laser.

14. The method of claim 10, further comprising adding conductive interconnects across the substrate junctions to provide electrical transmission lines across the substrate junctions and between respective circuit components on opposite sides of a respective substrate junction.

15. The method of claim 14, wherein adding the conductive interconnects comprises using three dimensional printing to apply conductive metal over the substrate junctions.

16. The method of claim 15, adding the conductive interconnects comprises printing silver paste as the conductive metal.

17. The method of claim 10, further comprising cutting the original substrate with a laser and using the laser to make a separating cut that is 15 microns wide.

18. An electrical circuit on a substrate comprising:
a plurality of modular substrate sections comprising circuit components thereon;
substrate junctions between the modular substrate sections, wherein the substrate junctions comprise respective side portions of respective substrate pieces mated with corresponding side portions of other substrate sections;
conductive interconnects positioned over sections of the substrate junctions to provide conductive electrical transmission lines between at least two circuit components that are on opposite sides of a respective substrate junction.

19. The electrical circuit of claim 18, wherein the conductive interconnects comprise printed metallic ink forming conductive metallic bridges over the substrate junctions.

20. The electrical circuit of claim 18, further comprising epoxy filler connecting the modular substrate sections at the substrate junctions.

21. The electrical circuit of claim 18, wherein the modular substrate sections are fabricated so that respective side portions of the respective substrate pieces are mated with corresponding side portions of other substrate sections that are also fabricated to match with the modular substrate sections.
